(19) United States
(12) Patent Application Publication
(10) Pub. No.: US 2026/0068161 A1
(43) Pub. Date: Mar. 5, 2026

(54) SEMICONDUCTOR MEMORY DEVICE AND ELECTRONIC SYSTEM INCLUDING THE SAME

(71) Applicant: SAMSUNG ELECTRONICS CO., LTD., Suwon-si (KR)

(72) Inventors: Sucheol Ju, Suwon-si (KR); Moonjong Kang, Suwon-si (KR); Inkyu Lee, Suwon-si (KR)

(21) Appl. No.: 19/201,683

(22) Filed: May 7, 2025

(30) Foreign Application Priority Data
Sep. 2, 2024 (KR) 10-2024-0118262

(51) Int. Cl. H10B 43/27; H10B 43/10; H10B 43/35; H10B 43/40

(52) U.S. Cl. CPC H10B 43/27; H10B 43/10; H10B 43/35; H10B 43/40

(57) ABSTRACT

A semiconductor memory device includes a substrate, a mold structure including a dummy pattern disposed on a partial area of the substrate, a plurality of mold insulating layers and a plurality of gate electrodes alternately stacked in a first direction on the substrate over the dummy pattern, and a first word line contact extending into the mold structure and in the first direction. The plurality of gate electrodes include a first gate electrode electrically connected to the first word line contact. The first gate electrode includes a first conductive plate portion extending in parallel with a surface of the substrate, a second conductive plate portion extending in parallel with the surface of the substrate and disposed at a vertical level different from the first conductive plate portion, and a conductive connection portion connecting the first conductive plate portion to the second conductive plate portion.

### CROSS-REFERENCE TO RELATED APPLICATION(S)

This application claims priority to Korean Patent Application No. 10-2024-0118262, filed in the Korean Intellectual Property Office on Sep. 2, 2024, the contents of which are hereby incorporated by reference in its entirety.

### BACKGROUND

Semiconductor memory devices capable of storing high volumes of data are in high demand in electronic systems requiring for data storage. Accordingly, some recent development efforts focus on methods for increasing the data capacity of semiconductor memory devices. For example, a semiconductor device featuring three-dimensionally arranged memory cells has been proposed instead of a conventional semiconductor device featuring two-dimensionally arranged memory cells.

### SUMMARY

In general, in some aspects, the present disclosure is directed toward a semiconductor memory device and an electronic system having improved electrical characteristics and reliability.

According to some implementations, the present disclosure is directed to a semiconductor memory device that comprises a substrate, a mold structure including a dummy pattern disposed on a partial area of the substrate, a plurality of mold insulating layers and a plurality of gate electrodes alternately stacked in a first direction on the substrate over the dummy pattern, and a first word line contact configured to penetrate (extend into) the mold structure and extend in the first direction, wherein the plurality of gate electrodes include a first gate electrode electrically connected to the first word line contact, wherein the first gate electrode includes a first conductive plate portion extending in parallel with a surface of the substrate, a second conductive plate portion extending in parallel with a surface of the substrate and disposed at a vertical level different from the first conductive plate portion, and a conductive connection portion for connecting the first conductive plate portion to the second conductive plate portion, wherein a thickness of the conductive connection portion is greater than a thickness of the first conductive plate portion and a thickness of the second conductive plate portion, wherein an inner surface of the conductive connection portion contacts an outer surface of the first word line contact.

According to some implementations, the present disclosure is directed to a semiconductor memory device that comprises a peripheral circuit structure, and a cell structure stacked on the peripheral circuit structure, wherein the cell structure includes a substrate including a cell array region and an extension region, a mold structure including a dummy pattern disposed on a partial area of the substrate, a plurality of mold insulating layers and a plurality of gate electrodes alternately stacked in a first direction on the substrate over the dummy pattern, a channel structure disposed in the cell array region, penetrating the mold structure, and extending in the first direction, and a first word line contact disposed in the extension region, penetrating the mold structure, and extending in the first direction, wherein the plurality of gate electrodes include a first gate electrode electrically connected to the first word line contact, wherein the first gate electrode comprises a first conductive plate portion extending in parallel with a surface of the substrate, a second conductive plate portion extending in parallel with a surface of the substrate and disposed at a vertical level different from the first conductive plate portion, and a conductive connection portion configured to connect the first conductive plate portion to the second conductive plate portion, wherein a thickness of the conductive connection portion is greater than a thickness of the first conductive plate portion and a thickness of the second conductive plate portion, and wherein an inner surface of the conductive connection portion contacts an outer surface of the first word line contact.

According to some implementations, the present disclosure is directed to an electronic system that comprises a main substrate, a semiconductor memory device including a peripheral circuit structure and a cell structure stacked on the peripheral circuit structure on the main substrate, and a controller electrically connected to the semiconductor memory device on the main substrate, wherein the cell structure includes a substrate including a cell array region and an extension region, a mold structure including a dummy pattern disposed on a partial area of the substrate, a plurality of mold insulating layers configured to cover the dummy pattern to be alternately stacked on the substrate in a first direction, and a plurality of gate electrodes, a channel structure disposed in the cell array region, penetrating the mold structure, and extending in the first direction, and a first word line contact disposed in the extension region, penetrating the mold structure, and extending in the first direction, wherein the plurality of gate electrodes include a first gate electrode electrically connected to the first word line contact, wherein the first gate electrode includes a first conductive plate portion extending in parallel with a surface of the substrate, a second conductive plate portion extending in parallel with a surface of the substrate and disposed at a vertical level different from the first conductive plate portion, and a conductive connection portion configured to connect the first conductive plate portion to the second conductive plate portion, wherein a thickness of the conductive connection portion is greater than a thickness of the first conductive plate portion and a thickness of the second conductive plate portion, and wherein an inner surface of the conductive connection portion contacts an outer surface of the first word line contact.

According to some implementations, the present disclosure is directed to processing steps that may be streamlined by maintaining an etching strop level for forming a plurality of word line contacts substantially the same, thereby improving the reliability of the semiconductor memory device.

### BRIEF DESCRIPTION OF THE DRAWINGS

Example implementations will be more clearly understood from the following detailed description, taken in conjunction with the accompanying drawings.

FIG. 1 is a plan view showing an example of a semiconductor memory device according to some implementations.

FIG. 2 is a cross-sectional view taken along line A-A of FIG. 1 according to some implementations.

FIG. 3 is a cross-sectional view taken along line B-B of FIG. 1 according to some implementations.

FIG. 4 is an enlarged view showing an example of a region Q1 of FIG. 2 according to some implementations.

FIG. 5 is an enlarged view showing an example of a region Q2 of FIG. 2 according to some implementations.

FIG. 6 is an enlarged view showing an example of a region Q3 of FIG. 5 according to some implementations.

FIG. 7 to FIG. 9 are views showing an example of a semiconductor memory device according to some implementations.

FIG. 10 and FIG. 11 are views showing an example of a semiconductor memory device according to some implementations.

FIG. 12 and FIG. 13 are views showing an example of a semiconductor memory device according to some implementations.

FIG. 14 is a view showing an example of a semiconductor memory device according to some implementations.

FIG. 15 is a view showing an example of a semiconductor memory device according to some implementations.

FIG. 16 to FIG. 21 are intermediate stage views showing an example of a manufacturing method of a semiconductor memory device according to some implementations.

FIG. 22 is a block view showing an example of an electronic system according to some implementations.

FIG. 23 is a perspective view showing an example of an electronic system including a semiconductor memory device according to some implementations.

FIG. 24 is a schematic sectional view taken along line V-V of FIG. 23 according to some implementations.

### DETAILED DESCRIPTION

Hereinafter, example implementations will be explained in detail with reference to the accompanying drawings.

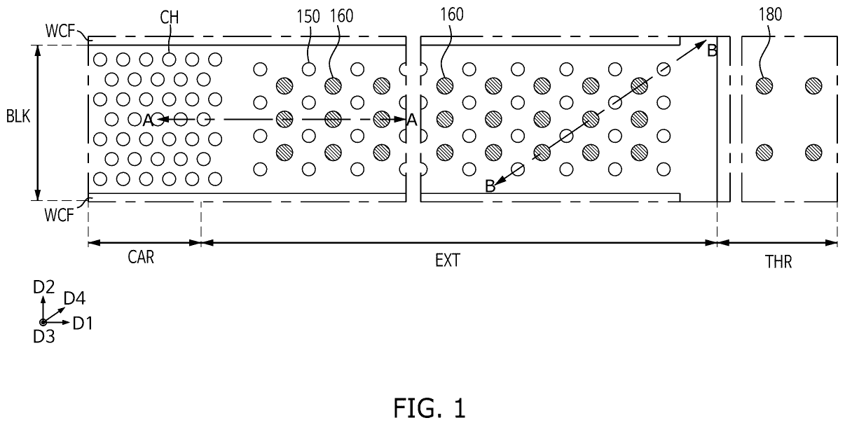

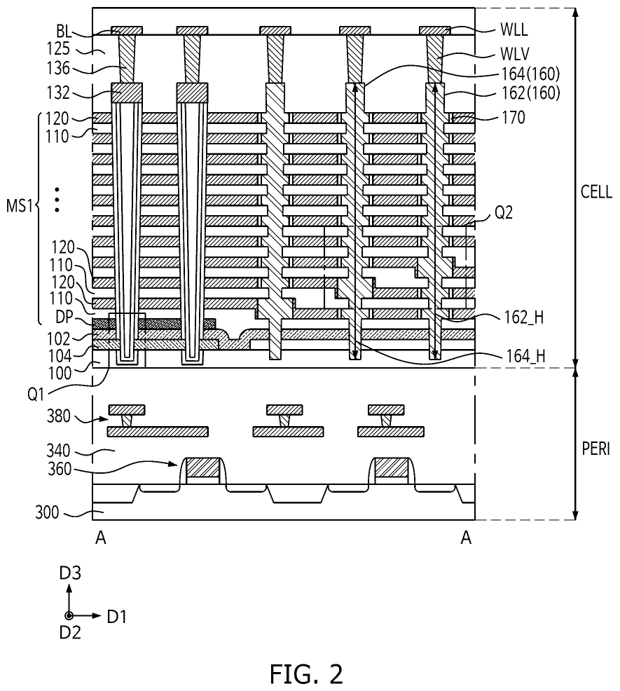

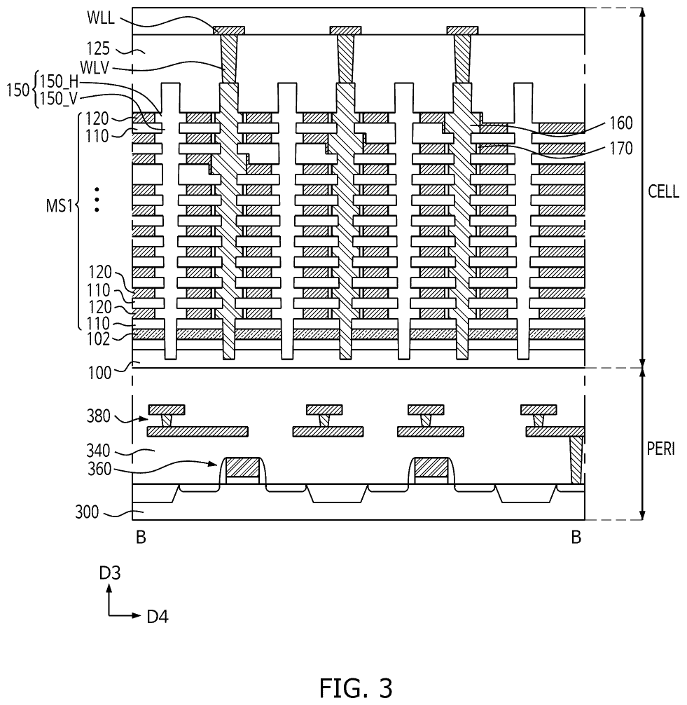

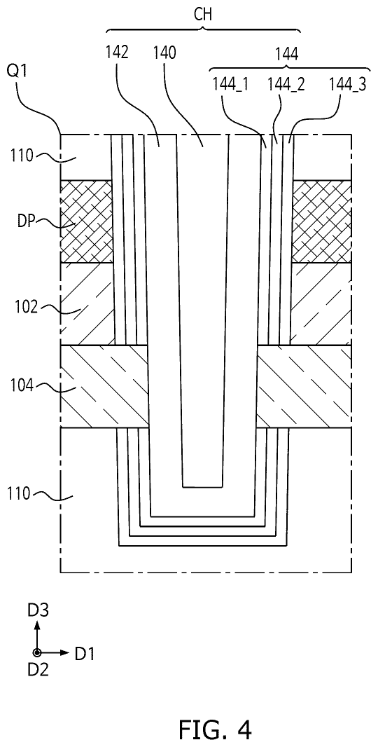

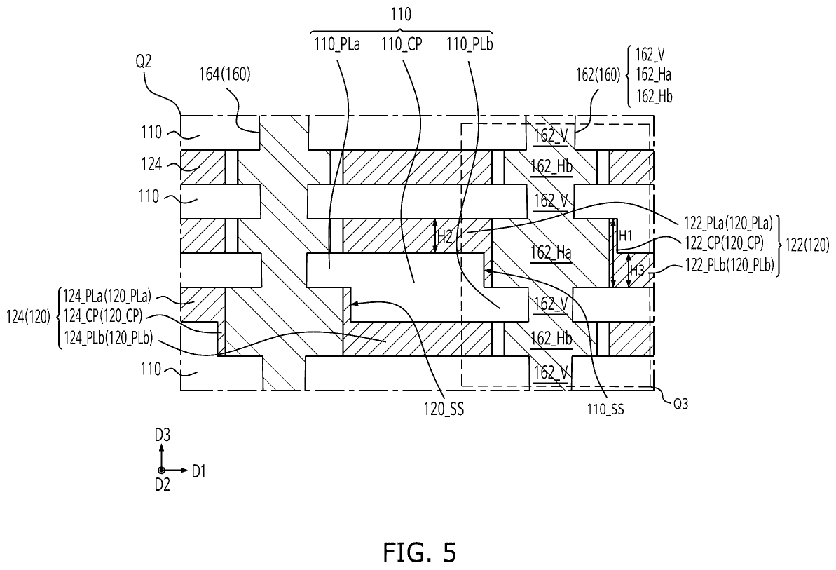

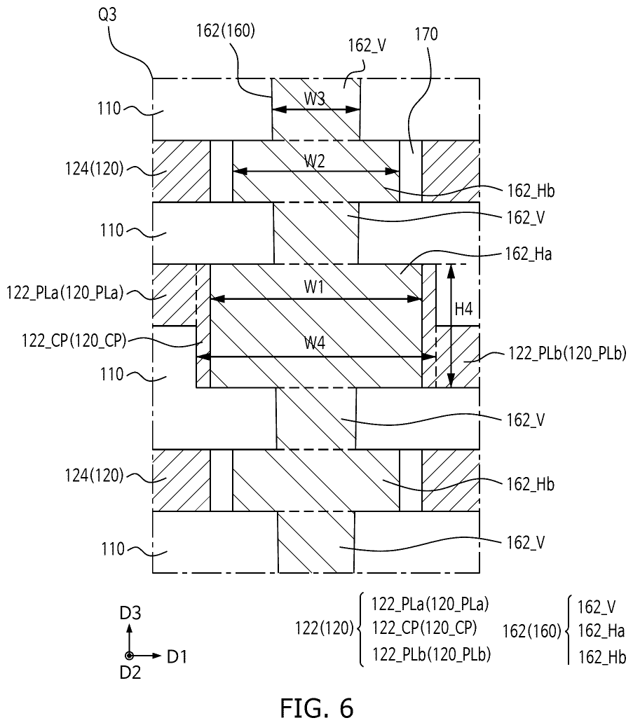

FIG. 1 is a plain view showing an example of a semiconductor memory device according to some implementations. FIG. 2 is a cross-sectional view taken along line A-A of FIG. 1 according to some implementations. FIG. 3 is a cross-sectional view taken along line B-B of FIG. 1 according to some implementations. FIG. 4 is an enlarged view showing an example of a region Q1 of FIG. 2 according to some implementations. FIG. 5 is an enlarged view showing an example of a region Q2 of FIG. 2 according to some implementations. FIG. 6 is an enlarged view showing an example of a region Q3 of FIG. 2 according to some implementations.

In FIG. 1 to FIG. 6, a semiconductor memory device may include a cell structure CELL and a peripheral circuit structure PERI. The cell structure CELL may include a cell substrate 100, a first mold structure MS1, a channel structure CH, a bit line BL, a word line contact 160, and a contact spacer 170. The cell structure CELL may further include components required for a semiconductor memory device in addition to the components in the drawings.

The cell substrate 100 may include a cell array region CAR, an extension region EXT, and a through region THR. A memory cell array including a plurality of memory cells may be formed in the cell array region CAR. The channel structure CH, the first mold structure MS1, the bit line BL, etc. may be disposed in the cell array region CAR. According to some implementations, the expression that component B is formed or disposed on component A is not limited that component B is formed or disposed in contact with component A. For example, according to some implementations, component C may be placed between component B and component A. The expression that component B is formed or disposed on component A is not limited to that component B is placed above component A in the drawings. For example, component B is disposed below, to the right, or to the left of component A.

The extension region EXT may be placed at the periphery of the cell array region CAR. For example, the extension region EXT may surround the cell array region CAR. The word line contact 160, the contact spacer 170, and the support structure 150 may be placed in the extension region EXT.

The through region THR may be placed outside the extension region EXT. For example, the through region THR may be placed on a side of the extension region EXT, but the present disclosure is not limited thereto. A source contact 180, an input and output contact, etc. may be placed in the through region THR.

The cell substrate 100 may be disposed in the peripheral structure PERI. The cell substrate 100 may include a semiconductor substrate, such as a silicon substrate, a germanium substrate, or a silicon-germanium substrate. In some implementations, the cell substrate 100 may include a silicon-on-insulator (SOI) substrate, a germanium-on-insulator (GOI) substrate, etc. In some implementations, the cell substrate 100 may include polysilicon (poly Si).

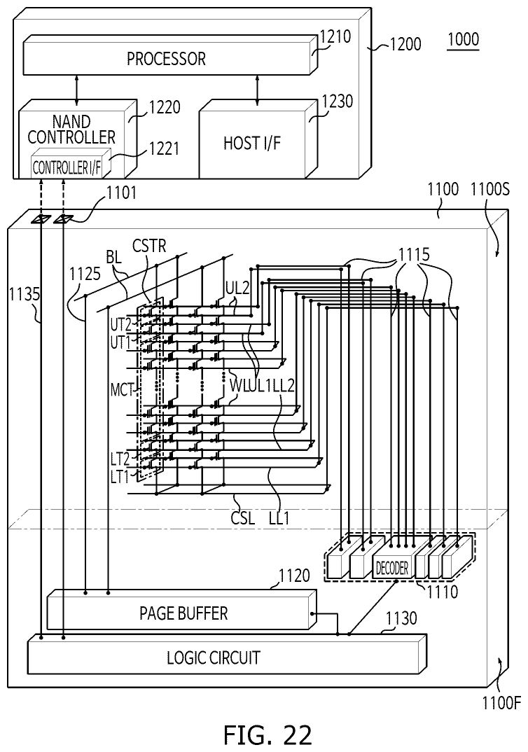

The source structures 102 and 104 may be formed on the cell substrate 100. The source structures 102 and 104 may be placed between the cell substrate 100 and the first mold structure MS1. For example, the source structure bodies 102 and 104 may extend along the upper surface of the cell substrate 100. The source structures 102 and 104 may be formed to contact the semiconductor pattern of the channel structure CH. For example, a second source layer 104 of the source structures 102 and 104 may penetrate (e.g., extend into) an information storage film 144 to contact the semiconductor pattern. The source structures 102 and 104 may be provided to a common source line (e.g., CSL of FIG. 22) of the semiconductor memory device. The source structures 102 and 104 may include polysilicon or metal doped with impurities, but it is not limited thereto.

According to some implementations, the channel structure CH may penetrate the source structures 102 and 104. For example, the lower part of the channel structure CH may penetrate the source structures 102 and 104 to be disposed in the cell substrate 100.

According to some implementations, the source structures 102 and 104 may be formed of multiple layers. For example, the source structures 102 and 104 may include a first source layer 102 and a second source layer 104 sequentially stacked on the cell substrate 100. The first source layer 102 and the second source layer 104 each may include poly silicon doped with impurities or poly silicon without impurities, but the present disclosure is not limited thereto. The first source layer 102 may contact the semiconductor pattern to be provided to the common source line (e.g., CSL of FIG. 22) of the semiconductor memory device. The second source layer 104 may be used for a support layer to prevent collapse or falling over of a mold stack (e.g., mold structures MS1 and MS2) in a replacement process for forming the first source layer 102.

In some implementations, a base insulating film may be placed between the cell substrate 100 and the first source structures 102 and 104. The base insulating film may include, for example, at least one of silicon oxide, silicon nitride, and silicon oxynitride, but is not limited thereto.

The mold structure MS1 may include a dummy pattern DP, a mold insulating layer 110, and a gate electrode 120. The dummy pattern DP may be disposed on a part of the cell substrate 100. The dummy pattern DP may extend in parallel with a side of the cell substrate 100 on the cell substrate 100, for example, in a first direction D1 and in a second direction 2. According to some implementations, the dummy pattern DP may be disposed in the cell array region CAR.

The dummy pattern DP may extend to the inside of the cell array region CAR or the boundary between the cell array CAR and the extension region EXT in the first direction D1. In FIG. 2, it is shown that the thickness of the dummy pattern DP is substantially the same as that of the mold insulating layer 110, but it is not limited thereto. The thickness of the dummy pattern DP may be different from that of the mold insulating layer 110.

The dummy pattern DP may include an insulating material. The dummy pattern DP may include, for example, at least one of silicon oxide, silicon nitride, and silicon oxynitride, but it is not limited to. According to some implementations, the dummy pattern DP may include the same material as the mold insulating layer 110. In this case, an interface may not be seen between the dummy pattern DP and the mold insulating layer 100 adjacent to the dummy pattern DP.

The mold insulating 110 and the gate electrode 120 may cover the dummy pattern DP to be alternately stacked in a third direction D3. The dummy pattern DP may protrude in the third direction D3 in the cell array region CAR, and the mold insulating layer 100 and the gate electrode 120 stacked on the top of the dummy pattern DP may form a stair-step structure. Due to such the stair-step structure, a step difference (e.g., a height difference) between the mold insulating 110 and the gate electrode 120 may exist, and the step difference may be formed in the extension region EXT.

The mold insulating layer 110 may include an insulating material. The mold insulating layer 110 may include, for example, at least one of silicon oxide, silicon nitride, and silicon oxynitride, but it is not limited to. The gate electrode 120 may include a conductive material. The gate electrode 120 may include, for example, a metal, such as tungsten (W), cobalt (Co), nickel (Ni), or a semiconductor material, such as silicon, but the present disclosure is not limited thereto.

According to some implementations, part of a plurality of gate electrodes 120 may be provided to a ground select line (GSL) of a semiconductor memory device. Another part of the plurality of gate electrodes 120 may be provided to a string select line (SSL) of the semiconductor memory device. For example, the gate electrode 120 adjacent to the source constructures 102 and 104 among the plurality of gate electrode 120 may be provided to the ground select line (GSL). The gate electrode 120 adjacent to the bit line BL among the plurality of gate lines 120 may be provided to the string select line (SSL). However, the present disclosure is not limited thereto. The arrangement and the number of the ground select lines GSL and string select lines SSL may vary.

An interlayer insulating layer 125 may be disposed in the first mold structure MS1 to cover the first mold structure MS1. The interlayer 125 may include at least one of low-k materials having a lower dielectric constant than silicon oxide, silicon oxynitride, but the present disclosure is not limited thereto.

The channel structure CH may be disposed in the cell array region CAR of the cell substrate 100. The channel structure CH may extend in the third direction D3 perpendicular to a surface of the cell substrate 100. The channel structure CH may penetrate the first mold structure MS1. For example, the channel structure CH may penetrate and intersect each of the plurality of gate electrodes 120. According to some implementations, in the cell array region CAR, the dummy pattern DP may be disposed between the cell substrate 100 and the first mold structure MS1. In this case, part of the plurality of channel structures CH may extend in the third direction D3 to penetrate the first mold structure MS1 and the dummy pattern DP.

The channel structure CH may have a pillar shape (e.g., a cylindrical shape) extending in the third direction D3. According to some implementations, the cross-section of the channel structure CH may have a sloped side that narrows in width as the channel structure gets closer to the cell substrate 100. However, the present disclosure is not limited thereto.

In FIG. 4, the channel structure CH may include a filling insulating layer 140, a semiconductor pattern 142, and an information storage film 144. The semiconductor pattern 142 may extend in the third direction D3 to penetrate the mold structure MS. It is shown that the semiconductor pattern 142 has a cup shape, but the present disclosure is not limited thereto. The semiconductor pattern 142 may have various shapes, for example, a cylindrical shape, a square cylinder shape, a solid filler shape, etc. The semiconductor pattern 142 may include a semiconductor material, such as single crystal silicon, polycrystalline silicon, an organic semiconductor material, and a carbon nanostructure, but the present disclosure is not limited thereto.

The information storage film 144 may be disposed between the semiconductor pattern 142 and each of the gate electrodes 120. For example, the information storage film 144 may extend along the outer surface of the semiconductor pattern 142. The information storage film 144 may include at least one of high-k materials having a higher dielectric constant than silicon oxide, silicon nitride, silicon oxynitride, and silicon oxide. The high-k material may include at least one of aluminum oxide, hafnium oxide, lanthanum oxide, tantalum oxide, titanium oxide, lanthanum hafnium oxide, lanthanum aluminum oxide, dysprosium scandium oxide, and combinations thereof.

According to some implementations, the channel structures may be disposed in a off-set shape. For example, as shown in FIG. 1, the channel structures CH may be disposed in a staggered manner in the first direction D1, and the second direction D2. The channel structure CH having the off-set shape may improve the integration density of the semiconductor device. According to some implementations, the channel structure CH may be disposed in a honeycomb shape.

According to some implementations, the storage insulating layer 1440 may be formed of multiple layers. The information storage layer 144 may include a tunnel insulating layer 1441, a charge storage layer 144_2, and a blocking insulating layer 1443 sequentially stacked on the outer surface of the semiconductor pattern 142.

The tunnel insulating layer 144_1 may include, for example, silicon oxide or a high-k material having a higher dielectric constant than silicon oxide (e.g., aluminum oxide (Al2O3), hafnium oxide (HfO2)). The charge storage layer 1442 may include, for example, silicon nitride. The blocking insulating layer 1443 may include, for example, silicon oxide or a high-k material having a higher dielectric constant than silicon oxide (e.g., aluminum oxide (Al2O3), hafnium oxide (HfO2)).

According to some implementations, the channel structure CH may further include the filling insulating layer 140. The filling insulating layer 140 may fill the inside of the semiconductor pattern 142 in a cup shape. The filling insulating layer 140 may include, for example, silicon oxide, but it is not limited thereto.

According to some implementations, a channel pad 132 may be disposed in the channel structure CH. The channel pad 132 may be formed to contact the semiconductor pattern 142. For example, the channel pad 132 may be provided inside the interlayer insulating layer 125 to contact an end of the semiconductor pattern 142. The channel pad 132 may include, for example, poly silicon doped with impurities, but the present disclosure is not limited thereto.

The first mold structure MS1 may be divided by word line cut regions WCF to form a memory cell block (e.g., BLK of FIG. 1). The word line cut region WCF may include, for example, silicon oxide, silicon nitride and silicon oxynitride, but it is not limited thereto.

The bit line BL may be formed in the first mold structure MS1. The bit line BL may intersect the word line cut regions WCF. For example, each of the bit lines BL may extend in the second direction D2. The bit lines BL may be arranged spaced apart from each other along the first direction D1.

The bit line BL may contact the channel structure CH arranged along the second direction D2. A bit line contact 136 may be formed inside the interlayer insulating layer 125. The bit line BL may be electrically connected to the channel structure CH through the bit line contact 136 and the channel pad 132.

The word line contact 160 may be disposed in the extension region EXT on the cell substrate 100. The word line contact 160 may extend in the third direction D3 perpendicular to a surface of the cell substrate 100. The word line contact 160 may penetrate the first mold structure MS1. For example, the word line contact 160 may penetrate and intersect each of the plurality of gate electrodes 130. The word line contact 160 may contact the corresponding gate electrode 120, for example, a select gate electrode. The word line contact 160 may be disconnected to a non-corresponding gate electrode, for example, a non-select gate electrode.

The word line contact 160 may include, for example, at least one of aluminum (Al), tungsten (W), cobalt (Co), ruthenium (Ru), silver (Ag), gold (Au), manganese (Mn), and molybdenum (Mo).

According to some implementations, the respective heights of a plurality of word line contacts 160 may correspond to one another. For example, the plurality of word line contacts 160 may include a first word line contact 162 and a second word line contact 164 spaced apart in a parallel direction to a side of the cell substrate 100 from the first word line contact 162. A height 162_H of the first word line contact 162 may be the same as a height 164_H of the second word line contact 164.

The contact spacer 170 may be disposed on part of the side surface of the word line contact 160. The contact spacer 170 may be disposed between the word line contact 160 and the non-select gate electrode. The contact spacer 170 may include an insulating material. The contact spacer 170 may include, for example, an insulating material of silicon oxide series.

In FIG. 5, it will be described in relation to the shape of the stair-step structure of the mold insulating layer 110 and the gate electrode 120, and the shape of the first word line contact 162 in detail. Each of the plurality of mold insulating layers 110 may have a stair-step structure. For example, each of the plurality of mold insulating layers 110 may include a step difference surface 110_SS formed by the thickness of the dummy pattern DP.

The mold insulating layer 110 may include a first insulating plate portion 110_Pla, a second insulating portion 110_PLb, and an insulating connection portion 110_CP. The first insulating plate portion 110_Pla may extend in parallel with a surface of the cell substrate 100. The second insulating plate portion 110_PLb may extend in parallel with a surface of the cell substrate 100 to be positioned at a vertical level different from the first insulating plate portion 110_Pla. The insulating connection portion 110_CP may connect the first insulating plate portion 110_Pla and the second insulating plate portion 110_PLb. The insulating connection portion 110_CP may extend in the third direction D3.

Each of the plurality of gate electrodes 120 may have a stair-step structure. For example, each of the plurality of gate electrodes 120 may include a step difference surface 120_SS formed by the thickness of the dummy pattern DP. The gate electrode 120 may include a first conductive plate portion 120_PLa, a second conductive plate portion 120_PLb, and a conductive connection portion 120_CP.

The first conductive plate portion 120_Pla may extend in parallel with a surface of the cell substrate 100. The second conductive plate portion 120_PLb may extend in parallel with a surface of the cell plate 100, and may be positioned at a vertical level different from the first conductive plate portion 120_Pla. For example, the second conductive plate portion 120_PLb may be at a lower vertical level than the first conductive plate portion 120_Pla. However, the present disclosure is not limited thereto.

The conductive connection portion 120_CP may connect the first conductive plate portion 120_Pla and the second conductive plate portion 120_PLb. The conductive connection portion 120_CP may extend in the third direction D3. Part of one side surface of the conductive connection portion 120_CP may be connected to one side surface of the first conductive plate portion 120_PLa. Part of the other side surface of the conductive connection portion 120_CP may be connected to one side surface of the second conductive plate portion 120_PLb.

A thickness H1 of the conductive connection portion 120_CP may be greater than a thickness H2 of the first conductive plate portion 120_PLa and a thickness H3 of the second conductive plate portion 120_PLb. For example, the thickness H1 of the conductive connection portion 120_CP may be the same as the distance between the top of the first conductive plate portion 120_PLa and the bottom of the second conductive plate portion 120_PLb. The upper part, the lower part, the upper surface, and the lower surface are expressed for convenience of explanation, but the present disclosure is not limited thereto. The upper part, the lower part, the upper surface, and the lower surface are described in reference to the drawings, but the terms indicating an upper and lower relationship while the drawing is rotated up and down may change.

The first word line contact 162 may indicate an arbitrary one word line contact 160 among the plurality of word line contacts 160. The plurality of gate electrodes 120 may include a first gate electrode 122 electrically connected to the first word line contact 162, and a second gate electrode 124 that is not electrically connected to the first word line contact 162. The first gate electrode 122 may be a select gate electrode, and the second gate electrode 124 may be a non-select gate electrode.

The first word line contact 162 may include a vertical contact portion 162_V, a first horizontal contact portion 162_Ha, and a second horizontal contact portion 162_Hb. The vertical contact portion 162_V may penetrate the plurality of mold insulating layers 110. The first horizontal contact portion 162_Ha may include the first horizontal contact portion 162_Ha penetrating the first gate electrode 122 and the second horizontal contact portion 162_Hb penetrating other gate electrodes among the plurality of gate electrodes 120, for example, the second gate electrode 124.

The first gate electrode 122 may include a 1-1 conductive plate portion 122_PLa, a 1-2 conductive plate portion 122_PLb, and a first conductive connection portion 122_CP. The 1-1 conductive plate portion 122_PLa, the 1-2 conductive plate portion 122_PLb, and the first conductive connection portion 122_CP may respectively correspond to the first conductive plate portion 120_PLa, the second conductive plate portion 120_PLb, and the conductive connection portion 120_CP. The second gate electrode 124 may include a 2-1 conductive plate portion 124_PLa, a 2-2 conductive plate portion 124_PLb, and a second conductive connection portion 124_CP. The 2-1 conductive plate portion 124_PLa, the 2-2 conductive plate portion 124_PLb, and the second conductive plate portion 124_CP may respectively correspond to the first conductive plate portion 120_PLa, the second conductive plate portion 120_PLb, and the conductive connection portion 120_CP.

The first word line contact 162 may penetrate the first conductive connection portion 122_CP. The inner surface of the first conductive connection portion 122_CP may contact the outer surface of the first word line contact 162. For example, the inner surface of the first conductive connection portion 122_CP may surround the outer surface of the first word line contact 162.

The first word line contact 162 may penetrate the first 2-1 conductive plate portion 124_PLa or the 2-2 conductive plate portion 124_PLb. For example, the first word line contact 162 may penetrate the 2-1 conductive plate portion 124_PLa of the second gate electrode 124 disposed on the upper part (e.g., a high vertical level) of the first gate electrode 122. The first word line contact 162 may penetrate the 2-2 conductive plate portion 124_PLb of the second gate electrode 124 disposed on the lower part of the first gate electrode 122 (e.g., a low vertical level). However, the present disclosure is not limited thereto. The first word line contact 162 may penetrate the 2-2 conductive plate portion 124_PLb of the second gate electrode 124 disposed on the upper part (e.g., a high vertical level) of the first gate electrode 122, and the 2-1 conductive plate portion 124_PLa of the second gate electrode 124 disposed on the lower part (e.g., a low vertical level) of the first gate electrode 122.

The contact spacer 170 may be disposed between the first word line contact 162 and the second gate electrode 124. For example, the contact spacer 170 may surround the first word line contact 162. The inner surface of the contact spacer 170 may contact the outer surface of the first word line contact 162. The outer surface of the contact spacer 170 may contact the inner surface of the second gate electrode 124.

In FIG. 6, the shape of the first word line contact 162 will be described in detail. According to some implementations, a width W1 of a first horizontal contact portion 162_Ha and a width W2 of a second horizontal contact portion 162 Hb may be greater than a width W3 of a vertical contact portion 162_V. For example, the width W1 of the first horizontal contact portion 162_Ha may be greater than the width W3 of the vertical contact portion 162_V. The width W2 of the second horizontal contact portion 162_HIb may be greater than the width W3 of the vertical contact portion 162_Hb.

According to some implementations, a height H4 of the first horizontal contact portion 162_Ha may correspond to the distance between the top of the 1-1 conductive plate portion 122_PLa and the bottom of the 1-2 conductive plate portion 122_PLb.

According to some implementations, the width W1 of the first horizontal contact portion 162_Ha may be smaller than a width W4 of the first conductive connection portion 122_CP. The width W1 of the first horizontal contact portion may be constant in the third direction D3, but it is not limited thereto.

According to some implementations, a barrier layer may be further disposed between the first horizontal contact portion 162_Ha and the first conductive connection portion 122_CP. The interface between the first horizontal contact portion 162_Ha and the first conductive connection portion 122_CP may be identified by the barrier layer. The barrier layer may include at least one of, for example, tantalum (Ta), tantalum nitride (TaN), titanium (Ti), titanium nitride (TiN), titanium silicon nitride (TiSiN), ruthenium (Ru), cobalt (Co), nickel (Ni), nickel boron (NiB), tungsten (W), tungsten nitride (WN), tungsten carbonitride (WCN), zirconium (Zr), zirconium nitride (ZrN), vanadium (V), vanadium nitride (VN), niobium (Nb), niobium nitride (NbN), platinum (Pt), iridium (Ir), rhodium (Rh), and a two-dimensional (2D) material.

In FIG. 1 to FIG. 3, a word line via WLV may be disposed on the word line contact 160. The word line via WLV may be disposed inside the interlayer insulating layer 125. The word line contact 160 may be electrically connected to a wiring line WLL through the word line via WLV.

The support structure 150 may be disposed in the extension region EXT of the cell substrate 100. The support structure 150 may be disposed spaced apart from the word line contact 160 in a direction parallel with a surface of the cell substrate 100. For example, the support structure 150 may be disposed spaced apart in an direction perpendicular to the third direction D3 from the word line contact 160. The support structure 150 may be disposed at the periphery of the word line contact 160. For example, four (4) of support structures 150 may be disposed around one word line contact 160, but it is not limited thereto. For example, three of the support structures 150 may be disposed around the one word line contact 160. The support structure 150 may support the first mold structure MS1 or the word line contact 160 to prevent the first mold structure MS1 or the word line contact 160 from collapsing or falling over.

The support structure 150 may include a vertical support portion 150_V penetrating the plurality of mold insulating layers 110 and a horizontal support portion 150_H penetrating the plurality of gate electrodes 120. The vertical support portion 150_V may extend in the third direction D3. The horizontal support portion 150_H may extend in a direction parallel with a surface of the cell substrate 100, for example, the first direction D1, the second direction D2, and a fourth direction D4. The vertical support portion 150_V of the support structure 150 may have a shape similar to that of the channel structure CH. The horizontal support portion 150_H of the support structure 150 may overlap the gate electrode 120 in a horizontal direction.

The support structure 150 may include an insulating material. For example, the support structure 150 may include an insulating material of silicon oxide series, but it is not limited thereto.

The peripheral circuit structure PERI may include a peripheral circuit substrate 300, a peripheral circuit element 360, and a peripheral circuit wiring structure 380.

The peripheral circuit substrate 300 may include a semiconductor substrate, such as a silicon substrate, a germanium substrate, or a silicon-germanium substrate. In some implementations, the peripheral circuit substrate 300 may include a silicon-on-insulator (SOI) substrate, a germanium-on-insulator (GOI) substrate, etc.

The peripheral circuit element 360 may be formed on the peripheral circuit substrate 300. The peripheral circuit element 360 may include a peripheral circuit that controls operation of the semiconductor memory device. For example, the peripheral circuit element 360 may include a logic circuit 1130, a page buffer 1120, a decoder 1110 of FIG. 22. The surface of the peripheral circuit substrate 300 on which the peripheral circuit element 360 is disposed may be referred to as a front side of the peripheral circuit substrate 300. The surface of the peripheral circuit substrate 300 opposite to the front side of the peripheral circuit substrate 300 may be referred to as a back side of the peripheral circuit substrate 300.

The peripheral circuit element 360 may include, for example, a transistor, but it is not limited thereto. For example, the peripheral circuit element 360 may include various passive elements including a capacitor, a resistor, an inductor, etc. in addition to various active elements such as a transistor, etc.

The peripheral circuit wiring structure 380 may be formed on the peripheral circuit element 360. For example, a second wiring insulating layer 340 may be formed on the front side of the peripheral circuit substrate 300, and the peripheral circuit wiring structure 380 may be formed inside the second wiring insulating film 340. The peripheral circuit wiring structure 380 may be electrically connected to the peripheral circuit element 360. The number of layers or the arrangement of the peripheral circuit wiring structure 380 is exemplary only but the present disclosure is not limited thereto.

According to some implementations, the cell structure CELL may be stacked on the peripheral circuit structure PERI. For example, the cell structure CELL may be stacked on the second wiring insulating layer 340.

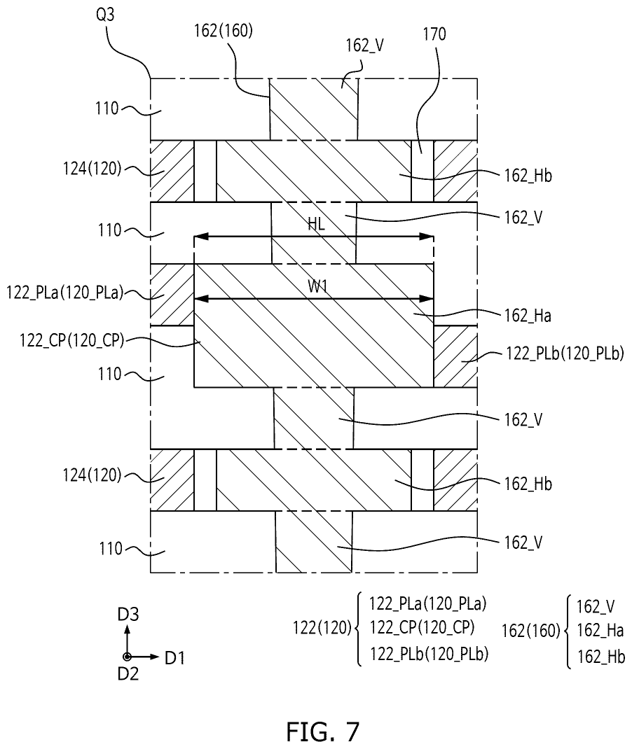

FIG. 7 to FIG. 9 are views showing an example of a semiconductor memory device according to some implementations. FIG. 7 to FIG. 9 correspond to an enlarged view of region Q3 of FIG. 5. The semiconductor memory device of FIG. 7 to FIG. 9 may be substantially the same as the semiconductor memory device described referring to FIG. 1 to FIG. 6, excluding the specific shape of the first word line contact 162. For convenience of explanation, the description will focus on the components different from those described in FIG. 1 to FIG. 6.

In FIG. 7, the width W1 of the first horizontal contact portion 162_Ha may correspond to a horizontal distance HL between a surface of the 1-1 conductive plate portion 122_PLa and a surface of the 1-2 conductive plate portion 122_PLb opposite to the surface of the 1-1 conductive plate portion 122_PLa.

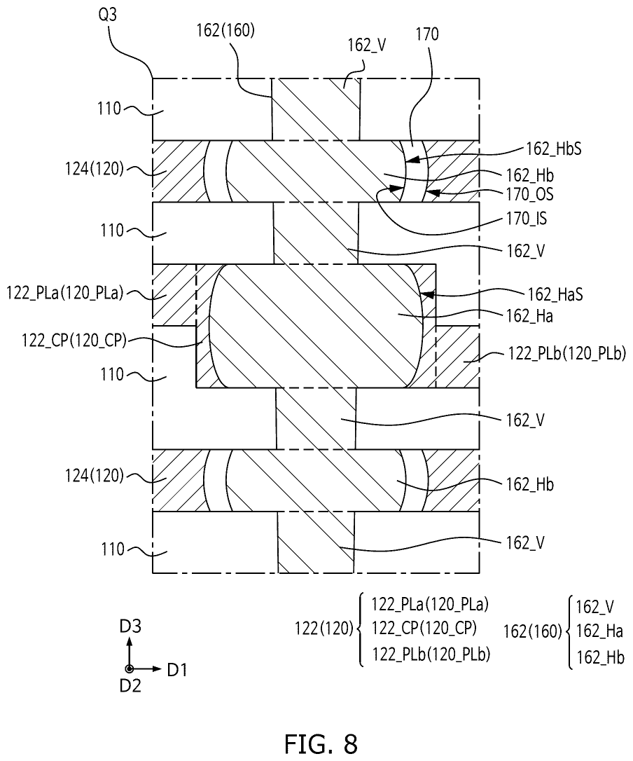

In FIG. 8, a surface 162_HaS of the first horizontal contact portion 162_Ha may have a convex shape that protrudes in the outward direction of the first horizontal contact portion 162_Ha. The width of the center of the first horizontal contact portion 162_Ha may be greater than the width of an edge portion. The inner surface of the first conductive connection portion 122_CP may have a concave shape corresponding to the shape of the first horizontal contact portion 162_Ha.

According to some implementations, a surface of 162_HbS of the second horizontal contact portion 162_Hb may have a convex shape that protrudes in the outward direction of the second horizontal contact portion 162_Hb. The width of the center of the second horizontal contact portion 162_Hb may be greater than the width of the edge portion. An inner surface 170_IS of the contact spacer 170 may have a concave shape corresponding to the shape of the second horizontal contact portion 162_Hb.

According to some implementations, the outer surface of the contact spacer 170 may have a convex shape that protrudes in the outward direction of the contact spacer 170. The surface of the second gate electrode 124 may have a concave shape corresponding to an outer surface 170_OS of the contact spacer 170.

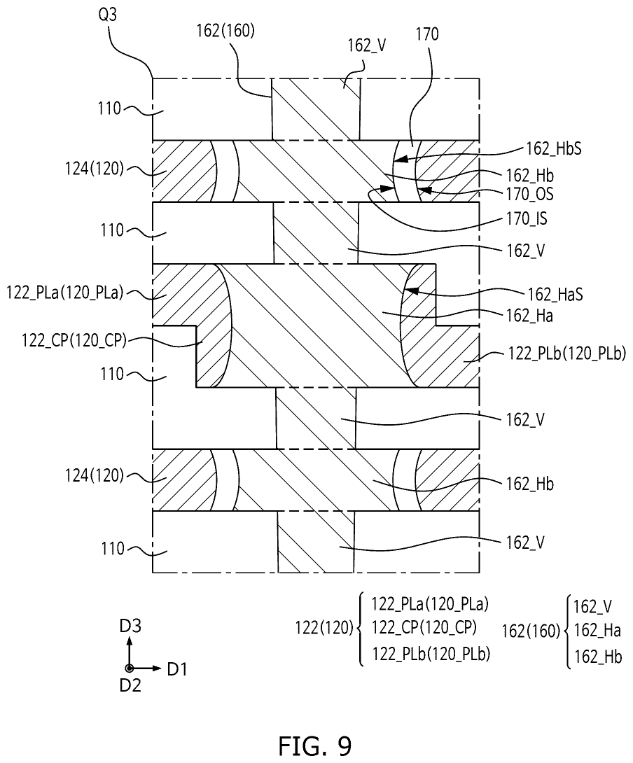

In FIG. 9, the surface 162_HaS of the first horizontal contact portion 162_Ha may have a concave shape that is recessed inwardly in the inner direction of the first horizontal contact portion 162_Ha. The width of the center of the first horizontal contact portion 162_Ha may be smaller than the width of the edge portion. The inner surface of the first conductive connection portion 122_CP may have a convex shape corresponding to the shape of the first horizontal contact portion 162_Ha.

According to some implementations, the surface 162_HbS of the second horizontal contact portion 162_Hb may have a concave shape recessed inwardly in the inner direction of the second horizontal contact portion 162_Hb. The width of the center of the second horizontal contact portion 162_Hb may be smaller than the width of the edge portion. An inner surface 170_IS of the contact spacer 170 may have a convex shape that corresponds to the shape of the second horizontal contact portion 162_Hb.

According to some implementations, the outer surface of the contact spacer 170 may have a concave shape recessed inwardly in the inner direction of the contact spacer 170. The surface of the second gate electrode 124 may have a convex shape that corresponds to the shape of an outer surface 170_OS of the contact spacer 170.

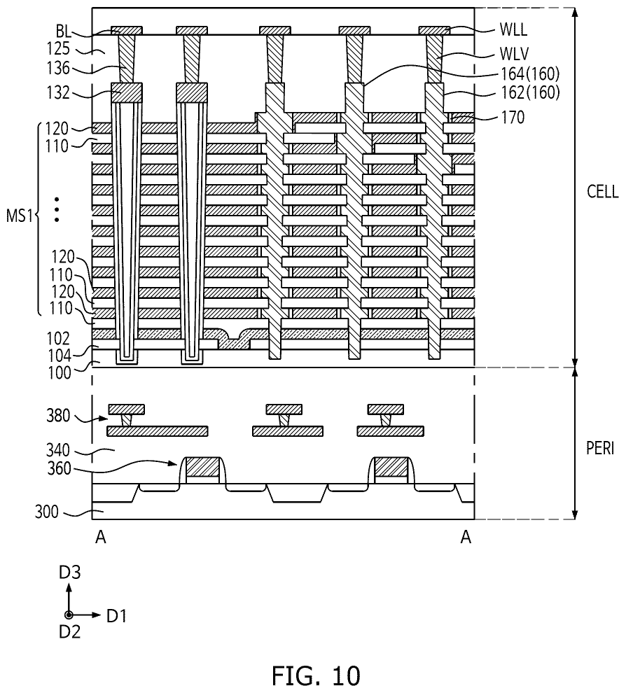

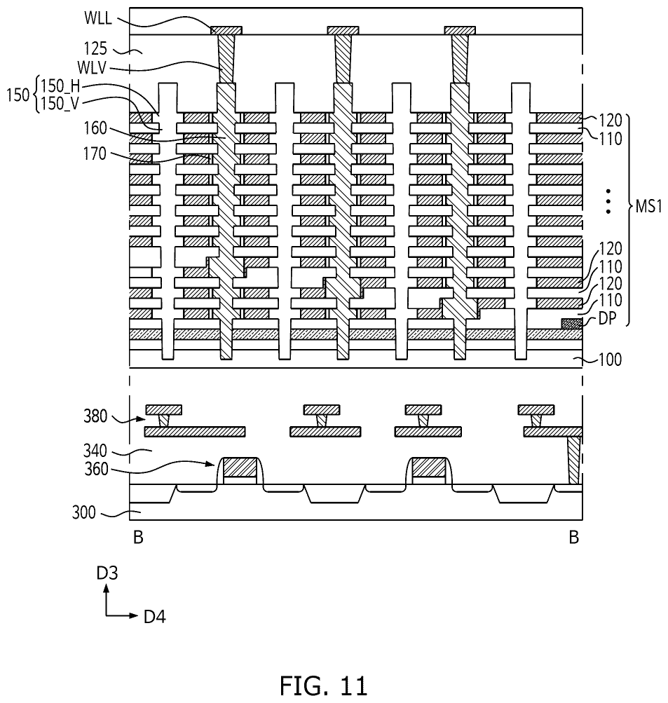

FIG. 10 and FIG. 11 are views showing an example of a semiconductor memory device according to some implementations. The semiconductor memory device of FIG. 10 and FIG. 11 may be substantially the same as the semiconductor memory device of FIG. 1 to FIG. 9, excluding the position of the dummy pattern DP. For convenience of explanation, the description will focus on components different from those described in FIG. 1 to FIG. 9.

According to some implementations, the dummy pattern DP may be disposed in the extension region EXT. The dummy pattern DP may extend to the inside of the extension region EXT or the boundary of the cell array region CAR in the first direction D1.

Due to the dummy pattern DP protruding in the third direction D3 in the extension region EXT, the mold insulating layer 110 and the gate electrode 120 stacked on the upper part of the dummy pattern DP may have a stair-step structure. Due to such the stair-step structure, the step difference (e.g., a height difference) may exist on the surfaces of the mold insulating layer 110 and the gate electrode 120, and the step difference may be formed in the extension region EXT. In this case, the step difference may not be formed in the cell array region CAR.

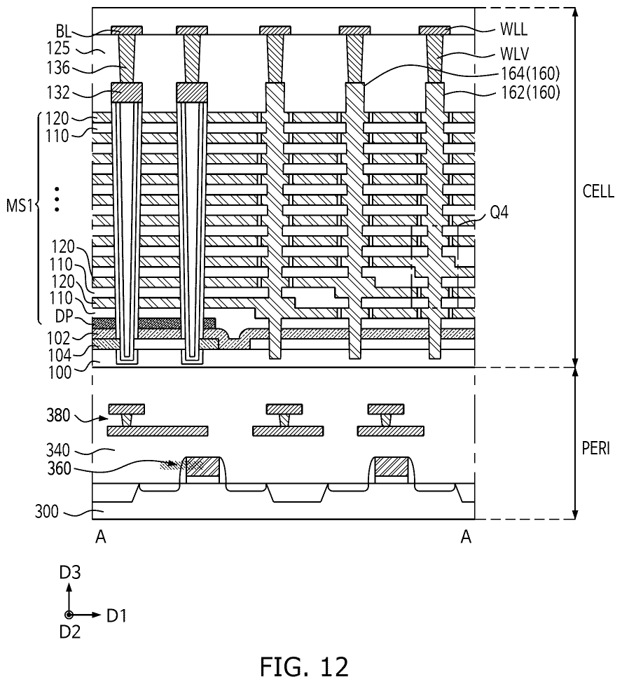

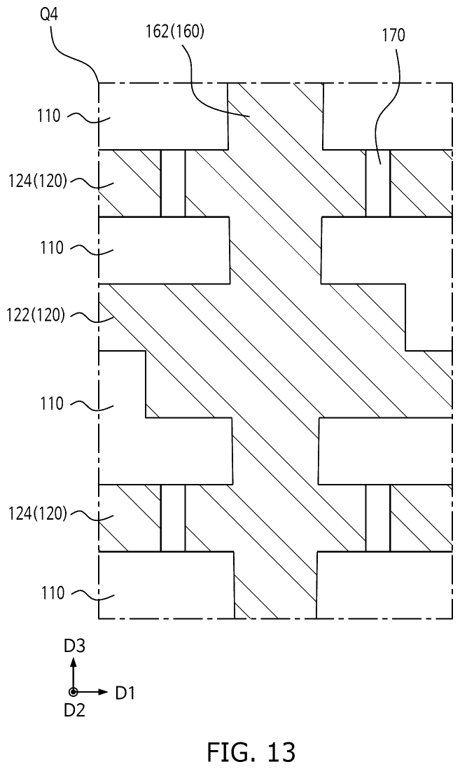

FIG. 12 and FIG. 13 are views showing an example of a semiconductor memory device according to some implementations. FIG. 12 is a cross-sectional view taken along line A-A of FIG. 1 according to some implementations. FIG. 13 is an enlarged view to explain area Q4 of FIG. 12 according to some implementations. The semiconductor memory device of FIG. 12 and FIG. 13 may be substantially the same as the semiconductor memory device described referring to FIG. 1 to FIG. 11, excluding the interface between the word line contact 160 and the first gate electrode 120_1. For convenience of explanation, the description will focus on the components different from those described in FIG. 1 to FIG. 11.

In FIG. 12. and FIG. 13, the first word line contact 162 and the first gate electrode 122 may be unitarily formed. For example, the first word line contact 162 and the first gate electrode 122 may be formed through the same process. The interface between the first word line contact 162 and the first gate electrode 122 may not be distinguished.

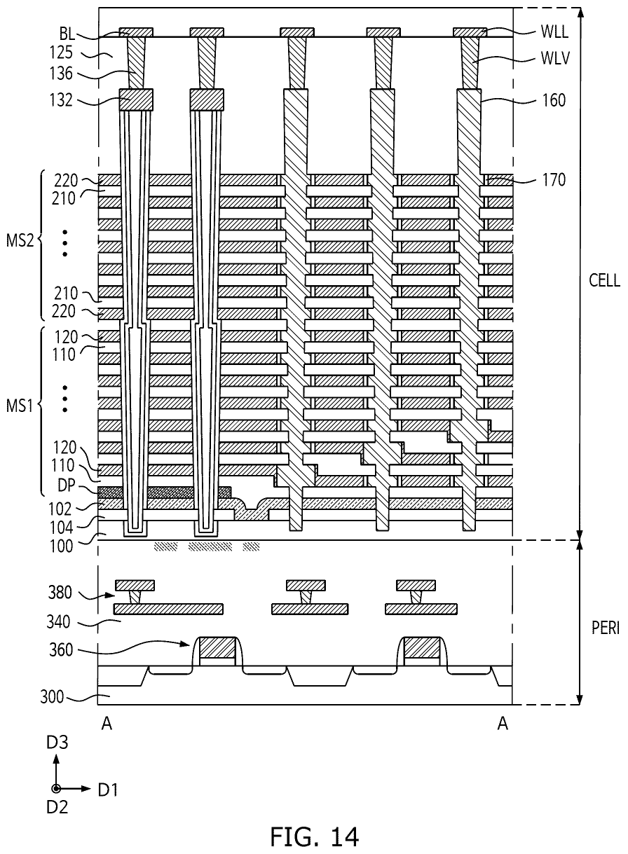

FIG. 14 is a view showing an example of a semiconductor memory device according to some implementations. FIG. 12 is a cross-sectional view taken along line A-A of FIG. 1 according to some implementations. The semiconductor memory device of FIG. 14 may be substantially the same as the semiconductor memory device described referring to FIG. 1 to FIG. 13, excluding that the plurality of mold structure MS1 and MS2 have a stacked structure. For convenience of explanation, the description will focus on the components different from those described in FIG. 1 to FIG. 13.

In FIG. 14, in a semiconductor memory device according to embodiments, the second mold structure MS2 and the first mold structure MS1 may be sequentially stacked on the cell substrate 100. The second mold structure MS2 may be disposed in the cell array region CAR and the extension region EXT of the cell substrate 100. The second mold structure MS2 may include the plurality of mold insulating layers 210 and the plurality of gate electrodes 22 alternately stacked in the third direction D3. The mold insulating layer 210 and the gate electrode 220 may have a layered structure that extends in parallel with a surface of the cell substrate 100.

The first mold structure MS1 may be disposed in the second mold structure MS2. The first mold structure MS1 may include the plurality of mold insulating layers 110 and the plurality of gate electrodes 120 alternately stacked in the third direction D3. The cell insulating layer may be disposed between the first mold structure MS1 and the second mold structure MS2. The cell insulating layer may cover the lower surface of the second mold structure MS2. The second mold structure MS2 may be formed on the cell insulating layer.

The channel structure CH may extend in the third direction D3 and penetrate the first mold structure MS1 and the second mold structure MS2. The channel structure CH may have a bending portion between the first mold structure MS1 and the second mold structure MS2.

The word line contact 160 may extend in the third direction D3, and penetrate the first mold structure MS1 and the second mold structure MS2. The plurality of word line contacts 160 may be electrically connected to the gate electrode 120 of the first mold structure MS1 and the gate electrode of the second mold structure MS2.

In FIG. 14, the number of mold structures MS1 and MS2 are limited to two (2), but the present disclosure is not limited thereto. For example, the number of mold structures MS1 and MS2 may be three (3), four (4), or more.

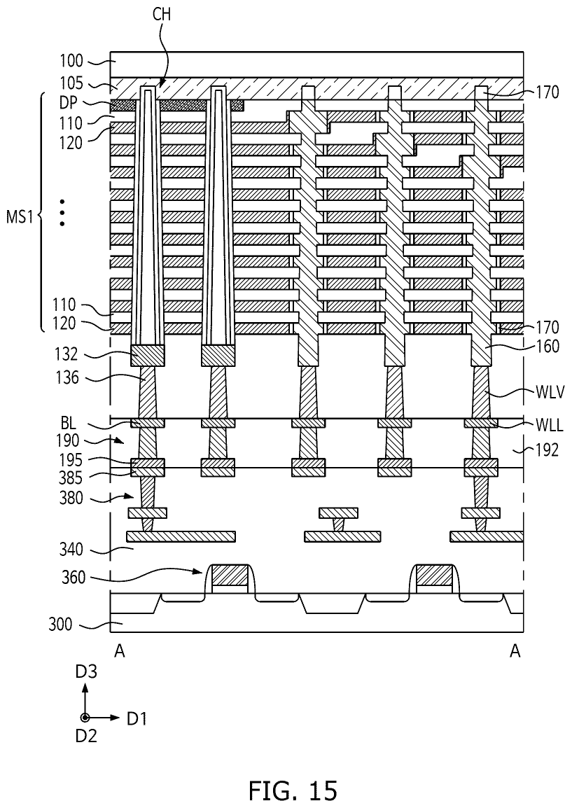

FIG. 15 is a view showing an example of a semiconductor memory device according to some implementations. FIG. 15 is a cross-sectional view taken along line A-A of FIG. 1 according to some implementations. The semiconductor memory device of FIG. 15 may be substantially the same as the semiconductor memory device in FIG. 1 to FIG. 15, except for having a chip-to-chip (C2C) structure. For convenience of explanation, the description will focus on the components different from those described in FIG. 1 to FIG. 15.

In FIG. 15, a semiconductor memory device according to embodiments may include a cell structure CELL and a peri structure PERI. The cell structure CELL may be disposed on the top of the peri structure PERI. The description of the peri structure PERI may be the same as that in FIG. 1 to FIG. 6. The cell structure CELL may include a cell substrate 100, a common source plate 105, a mold structure MS1, a channel structure CH, a bit line BL, a word line contact 160, a contact spacer 170, a cell wiring structure 190, etc.

The cell substrate 100 may be disposed in the peri structure PERI. The cell substrate 100 may include a semiconductor substrate, such as a silicon substrate, a germanium substrate, or a silicon-germanium substrate. In some implementations, the cell substrate 100 may include a silicon-on-insulator (SOI) substrate, a germanium-on-insulator (GOI) substrate, etc. In some implementations, the cell substrate 100 may include impurities. For example, the cell substrate 100 may include an n-type impurity (e.g., phosphorus (P), arsenic (As), etc.).

The common source plate 105 may be disposed on a surface of the cell substrate 100. The common source plate 105 may be disposed in the cell array region CAR, the extension region EXT and the through region THR. The common source plate 105 may contact the channel structure CH. For example, the common source plate 105 may be electrically connected to the semiconductor pattern (e.g., 142 of FIG. 4) of the channel structure CH. The common source plate 105 may contact the source contact (e.g., 180 of FIG. 1) in the through region THR of the cell substrate 100. The common source plate 105 may be provided to a common source line (e.g., CSL of FIG. 22) of the semiconductor memory device. According to some implementations, the common source plate 105 may contact a word line contact structure including the word line contact 160 and the contact spacer 170. For example, an end of the word line contact structure may be disposed inside the common source plate 105. In this case, the contact spacer 170 may be disposed on the end of the word line contact structure. Accordingly, the word line contact line 160 and the common source plate 105 may not directly contact each other.

The common source plate 105 may include, for example, polycrystalline silicon or a metal doped with impurities, but the present disclosure is not limited thereto.

The mold structure MS1 may be disposed on the common source plate 105. The mold structure MS1 may include the plurality of mold insulating layers 110 and the plurality of gate electrodes 120 alternately stacked in the third direction D3. The plurality of gate electrodes 120 may be spaced apart from each other and alternately stacked on the common source plate 105.

The cell wiring structure 190 may be formed in the mold structure MS1. For example, a first wiring insulating layer 192 may be formed on the interlayer insulating layer 125, and the cell wiring structure 190 may be formed inside the first wiring insulating layer 192. The cell wiring structure 190 may be electrically connected to the bit line BL and the word line contact 160. The cell wiring structure 190 may be electrically connected to the channel structure CH and the gate electrode 120. The number of layers or the arrangement of the cell wiring structures 190 may be exemplary only, but it is not limited thereto.

In some implementations, a semiconductor memory device may include a chip-to-chip (C2C) structure. The C2C structure may consist of an upper chip including the cell structure CELL on a first wafer (e.g., the cell substrate 100), and a lower chip including the peripheral circuit structure PERI on a second wafer (e.g., the peripheral circuit substrate 300) different from the first wafer, whereby the upper chip and the lower chip are connected to each other by bonding.

According to some implementations, the bonding method may be a method in which a first bonding metal 195 formed on the uppermost metal layer of the upper chip is electrically connected to a second bonding metal 385 formed on the uppermost metal layer of the lower chip. For example, when the first bonding metal 195 and the second bonding metal 385 are formed of copper Cu, the bonding method may be a Cu-Cu bonding method. However, it is exemplary only, and the first bonding metal 195 and the second bonding metal 385 may be formed of various metal, such as aluminum (Al) or tungsten (W).

As the first bonding metal 195 is bonded to the second bonding metal 385, the cell wiring structure 190 may be connected to the peripheral circuit wiring structure 380. The bit line BL and each of the plurality of gate electrode 120 may be electrically connected to the peripheral circuit element 360.

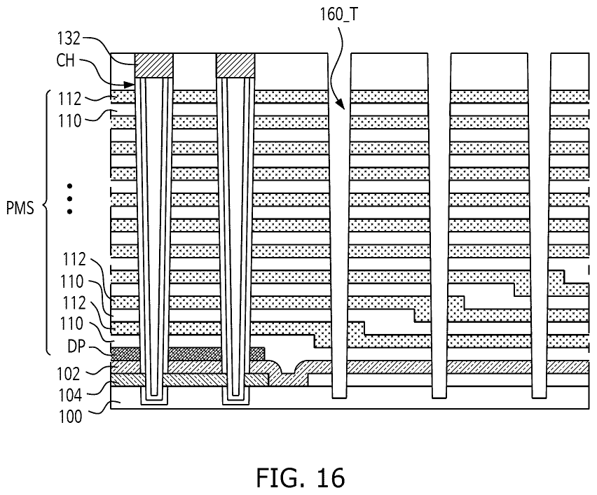

FIG. 16 to FIG. 21 are intermediate stage views showing an example of a manufacturing method of a semiconductor memory device according to some implementations. In FIG. 16, a pre-stacked structure PMS may be formed on the cell substrate 100. The pre-stacked structure PMS may include a dummy pattern DP disposed on part of the cell substrate 100, a plurality of mold insulating layer 110 and a plurality of mold sacrificial layers alternately stacked to cover the dummy pattern DP. The dummy pattern DP may protrude in the third direction D3 on the cell substrate 100. Accordingly, the mold insulating layer 110 and the mold sacrificial layer 112 stacked on the upper part of the dummy pattern DP may have a stair-step shape. The dummy pattern DP may be formed by using various patterning technologies. For example, the dummy pattern DP may be formed by using techniques such as nano-imprint lithography, photolithography, electron beam lithography, and x-ray lithography, but the present disclosure is not limited thereto.

The channel structure CH may be formed in the pre-stacked structure PMS. The channel pad 132 may be formed in the channel structure CH.

A word line contact trench 160_T may be formed in the pre-stacked structure PMS. The word line contact trench 160_T may penetrate the pre-stacked structure PMS. According to some implementations, the word line contact trench 160_T may be formed in an area in which a step difference is formed of the mold sacrificial layer 112. The word line contact trench 160_T may be formed by penetrating the mold sacrificial layer 112, which is thickened due to the step difference.

According to some implementations, the bottom surface of the word line contact trench 160_T may expose the cell substrate 100. The bottom surface of each of the plurality of word line contact trenches 160_T may be disposed at substantially the same vertical level. The etch stop level of each of the plurality of word line contact trenches 160_T may be substantially the same.

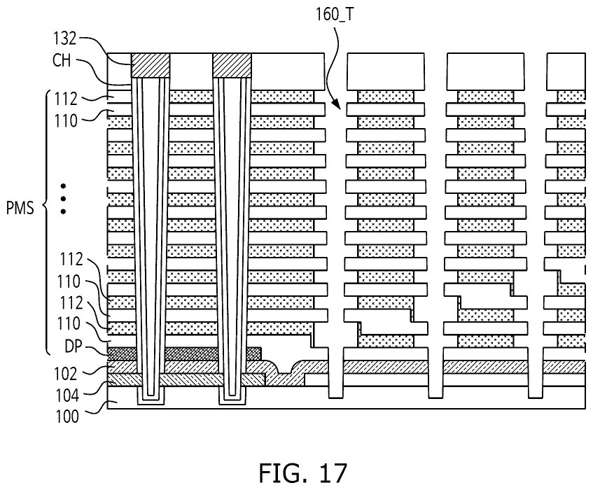

In FIG. 17, part of the mold sacrificial layer 112 on the sidewall of the word line contact trench 160_T may be removed in the direction in parallel with a surface of the cell substrate 100. The width of the word line contact trench 160_T may extend outwardly at the same vertical level as the mold sacrificial layer 112. The width of the word line contact trench 160_T at the same vertical level as the mold sacrificial layer 112 may be greater than that of the word line contact trench 160_T at the same vertical level as the mold insulating layer 110.

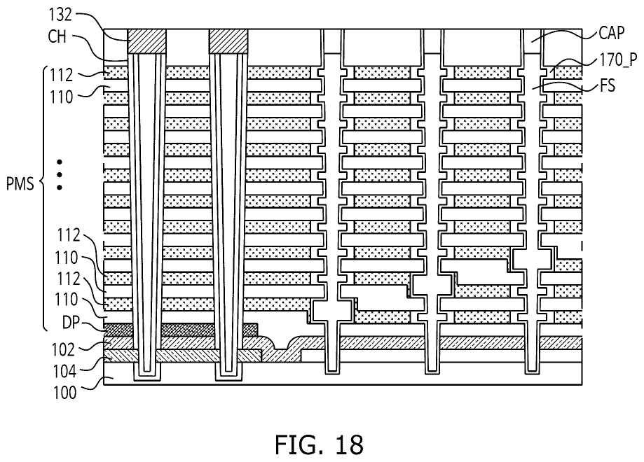

In FIG. 18, a free contact spacer 170_P may be formed on the sidewall or the bottom surface of the word line contact trench 160_T. According to some implementations, the thickness of the free contact spacer 170_P formed at the inner wall of the thick mold sacrificial layer 112 may be smaller than that of the free contact spacer 170_P formed at the inner walls of other mold sacrificial layers 112. A filling sacrificial layer FS may be formed on the free contact spacer 170_P. The capping layer CAP may be formed on the filling sacrificial layer FS.

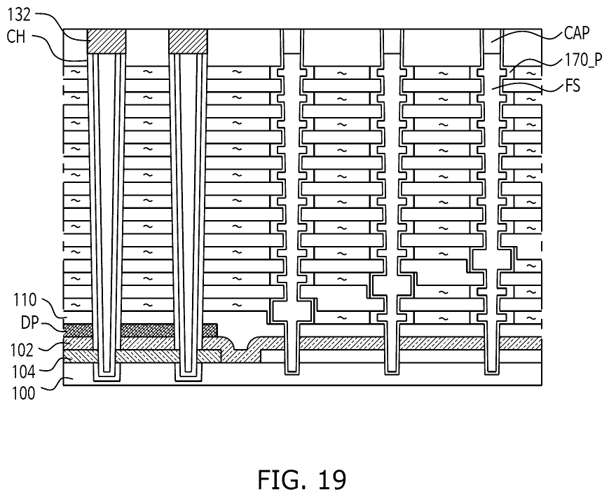

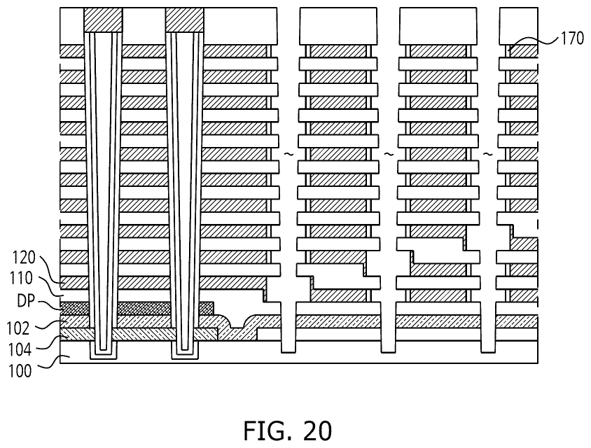

In FIG. 19 and FIG. 20, the mold sacrificial layer 112 may be removed. The gate electrode 120 may be disposed between the mold insulating layers 110. The capping layer CAP and the filling sacrificial layer FS may be removed. Part of the free contact spacer 170_P may be removed and the contact spacer 170 may be formed. The free contact spacer 170_P on the sidewall of the thick gate electrode 170_P formed at the step-difference of the mold insulating layer 110 and the gate electrode 120 may be removed, and the contact spacer 170 at the sides of other gate electrodes 120 may remain, thereby forming the contact spacer 170.

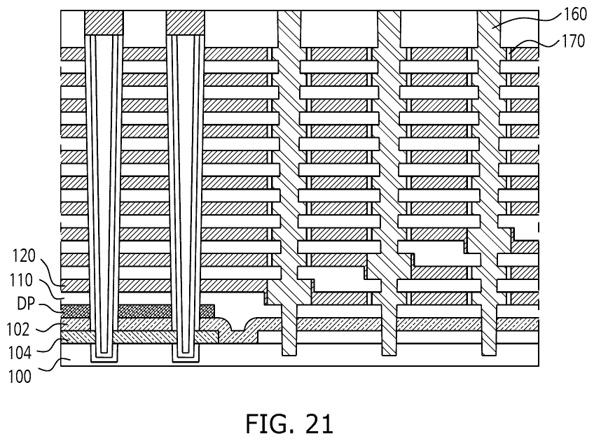

In FIG. 21, the word line contact 160 may be formed in the area where the capping layer CAP and the filling sacrificial layer FS are removed. The shape of the word line contact 160 may be the same as those described in FIG. 1 to FIG. 9.

According to some implementations, the word line contact 160 and the gate electrode 120 may be formed by using the same process. The interface between the word line contact 160 and the gate electrode 120 may not be distinguished. The shapes of the word line contact 160 and the gate electrode 120 may be the same as those in the FIG. 12 and FIG. 13.

FIG. 22 is a block view showing an example of an electronic system according to some implementations. In FIG. 22, an electronic system 1000 may include a semiconductor memory device 1100 described in FIG. 1 to FIG. 15 and a controller 1200 electrically connected to the semiconductor memory device 1100. The electronic system 1000 may be a storage device including one or a plurality of semiconductor memory devices 1100 or an electronic device including a storage device. For example, the electronic system 1000 may be a solid state drive device (SSD), a universal serial bus (USB), a computing system, a medical device, or a communication device.

The semiconductor memory device 1100 may be, for example, a NAND flash memory device described referring to FIG. 1 to FIG. 15. The semiconductor memory device 1100 may include a first structure 1100F and a second structure 1100S on the first structure 1100F. The first structure 1100F may be a peripheral circuit structure including a decoder circuit 1110, a page buffer 1120, and a logic circuit 1130. The second structure 1100S may be a memory cell structure including a bit line BL, a common source line CSL, a word line WL, first and second gate upper lines UL1 and UL2, first and second gate lower lines LL1 and LL2, and a memory cell string CSTR between the bit line BL and the common source line CSL.

In the second structure 1100S, each of memory cell strings CSTR may include lower transistors LT1 and LT2 adjacent to the common source line CSL, upper transistors UT1 and UT2 adjacent to the bit line BL, a plurality of memory cell transistors MCT disposed between the lower transistors LT1 and LT2 and the upper transistors UT1 and UT2. The number of lower transistors LT1 and LT2 and the number of upper transistors UT1 and UT2 may vary according to embodiments.

According to some implementations, the upper transistors UT1 and UT2 may include a string select transistor and the lower transistors LT1 and LT2 may include a ground select transistor. The gate lower lines LL1 and LL2 may be the gate electrodes of the lower transistors LT1 and LT2, respectively. The word line WL may be the gate electrodes of the memory cell transistor MCT, and the gate upper lines UL1 and UL2 may be the gate electrodes of the upper transistors UT1 and UT2, respectively.

The common source line CSL, the first and second gate lower lines LL1 and LL2, the word line WL, and the first and second gate upper lines UL1 and UL2 may be electrically connected to a decoder circuit 1110 through a first connection wiring 1115 that extends to the second structure 1100S in the first structure 1100F. The bit line BL may be electrically connected to a page buffer 1120 through a second connection wiring 1125 that extends to the second structure 1100S in the first structure 1100F.

In the first structure 1100F, the decoder circuit 1110 and page buffer 1120 may execute a control operation for at least one select memory cell transistor among the plurality of memory cell transistors MCT. The decoder circuit 1110 and the page buffer 1120 may be controlled by the logic circuit 1130. The semiconductor memory device 1100 may communicate with a controller 1200 through an input and output pad 1101 electrically connected to the logic circuit 1130. The input and output pad 1101 may be electrically connected to the logic circuit 1130 through the input and output connection wiring 1135 that extends to the second structure 1100S in the first structure 1100F.

The controller 1200 may include a processor 1210, a NAND controller 1220, and a host interface 1230. According to some implementations, the electronic system 1000 may include the plurality of semiconductor memory devices 1100, and the controller 1200 may control the plurality of semiconductor memory devices 1100.

The processor 1210 may control the overall operation of the electronic system 1000 including the controller 1200. The processor 1210 may operate according to a predetermined firmware, and control the NAND controller 1220 to access the semiconductor memory device 1100. The NAND controller 1220 may include a NAND interface 1221 that processes communication with the semiconductor memory device 1100. Through the NAND interface 1221, a control command for controlling the semiconductor memory device 1100, data for recording in the memory cell transistor MCT of the semiconductor memory device 1100, and data to be read from the memory cell transistor MCT of the semiconductor memory device 1100 may be transmitted. The host interface 1230 may provide a communication function between the electronic system 1000 and an external host. When receiving a control command from the external host through the host interface 1230, the processor 1210 may control the semiconductor memory device 1100 by responding to the control command.

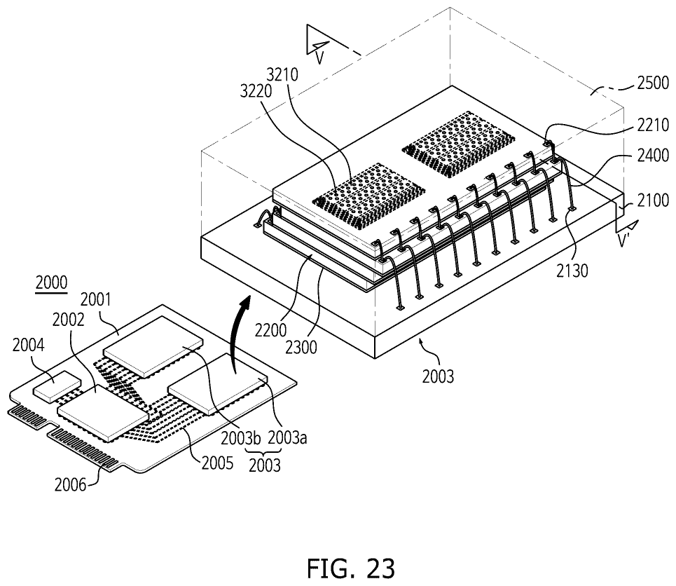

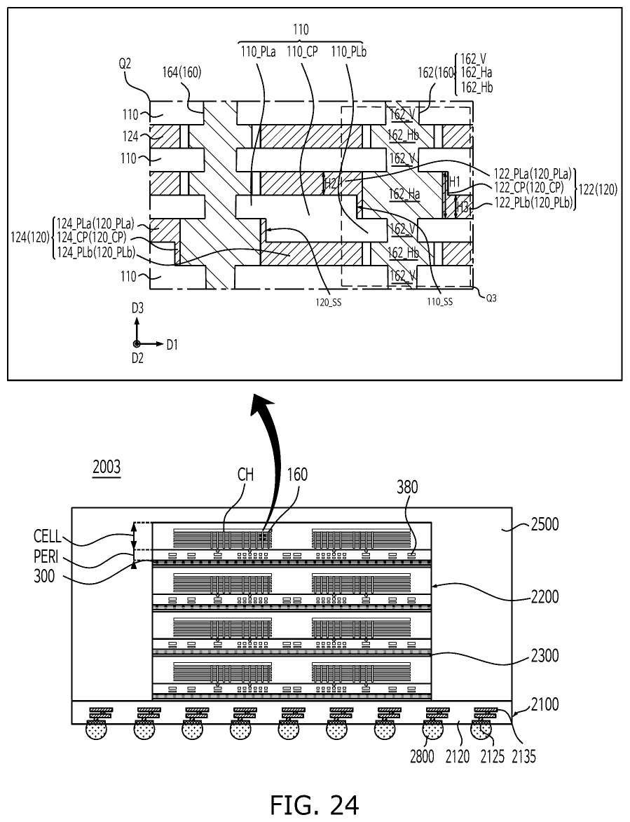

FIG. 23 is a perspective view showing an example of an electronic system including a semiconductor memory device according to some implementations. FIG. 24 is a schematic cross-sectional view taken along line V-V of FIG. 23 according to some implementations.

In FIG. 23, an electronic system 2000 may include a main substrate 2001, a controller 2002 embedded in the main substrate 2001, at least one or more semiconductor packages 2003, and a DRAM 2004. The semiconductor package 2003 and the DRAM 2004 may be electrically connected to the controller 2002 through a wiring pattern 2005 formed on the main substrate 2001.

The main substrate 2001 may include a connector 2006 including a plurality of pins coupled with an external host. The number and arrangement of the plurality of pins may vary according to a communication interface between the electronic system 2000 and the external host in the connector 2006. In some implementations, the electronic system 2000 may communicate with an external host according to one of the interfaces, such as Universal Serial Bus (USB), Peripheral Component Interconnect Express (PCI-Express), Serial Advanced Technology Attachment (SATA), M-Phy for Universal Flash Storage (UFS), etc. According to some implementations, the electronic system 2000 may operate by power supplied from the external host through the connector 2006. The electronic system 2000 may further include the controller 2002 supplied from the external host and a Power Management Integrated Circuit (PMIC) distributed in semiconductor packages 2003.

The main controller 2002 may record data in the semiconductor package 2003, and read data from the semiconductor package 2003, and improve the operation speed of the electronic system 2000.

The DRAM 2004 may be a buffer memory for reducing the speed difference between the semiconductor package 2003 which is a data storage space and the external host. The DRAM 2004 included in the electronic system 2000 may operate as a cache memory, and provide a space for arbitrarily storing data in the control operation for the semiconductor package 2003. When the DRAM 2004 is included in the electronic system 2000, the main controller 2002 may further include the DRAM controller for controlling the DRAM 2004 in addition to the NAND controller for controlling the semiconductor package 2003.

The semiconductor package 2003 may include a first semiconductor package 2003a and a second semiconductor package 2003b spaced apart from each other. Each of the first semiconductor package 2003a and the second semiconductor package 2003b may be a semiconductor package including a plurality of semiconductor chips 2200. Each of the first semiconductor package 2003a and the second semiconductor package 2003b may include a package substrate 2100, a semiconductor chip 2200 on the package substrate 2100, and an adhesive layer 2300 disposed on the lower surface of each of the semiconductor chips 2200, a connection structure 2400 electrically connecting the semiconductor chip 2200 to the package substrate 2100, a molding layer 2500 covering the semiconductor chip 2200 and the connection structure 2400 on the package substrate 2100.

The package substrate 2100 may be a printing circuit substrate including a package upper pad 2130. Each of the semiconductor chips 2200 may include an input and output pad 2210. The input and output pad 2210 may correspond to the input and output pad 1101 of FIG. 22. Each of the semiconductor chips 2200 may include a metal line 3210 and a channel structure 3220. Each of the semiconductor chips 2200 may include a semiconductor memory device described referring to FIG. 1 to FIG. 15.

According to some implementations, the connection structure 2400 may be a bonding wire electrically connecting the input and output pad 2210 to the package upper pad 2130. Accordingly, in each of the first semiconductor package 2003a and the second semiconductor package 2003b, the semiconductor chips 2200 may be electrically connected to each other in a bonding wire method, and electrically connected to the package upper pad 2130 of the package substrate 2100. According to some implementations, in each of the first semiconductor package 2003a and the second semiconductor package 2003b, the semiconductor chip 2200 may be electrically connected to one another through a connection structure including through silicon via (TSV) instead of the connection structure 2400 in a boning wire method.

According to some implementations, the main controller 2002 and the semiconductor chip 2200 may be included in one package. According to some implementations, the main controller 2002 and the semiconductor chip 2200 may be embedded in the main substrate 2001 and separate interposer substrate, and the main controller 2002 and the semiconductor chip 2200 may be electrically connected one another by the wires formed on the interposer substrate.

According to some implementations, the package substrate 2100 may be a printing circuit substrate. The package substrate 2100 may include a package substrate body 2120, a package upper pad 2130 disposed on the upper surface of the package substrate body 2120, and a lower pad 2125 disposed on the lower surface of the package substrate body 2120 or exposed through the lower surface, and an inner wiring 2135 electrically connecting the upper pad 2130 to the lower pad 2125 in the package substrate body 2120. The upper pad 2130 may be electrically connected to the connection structure 2400. The lower pad 2125 may be connected to the wiring pattern 2005 of the main substrate 2001 of the electronic system 2000 as described in FIG. 23 through a conductive connection portion 2800.

In the electronic system according to some implementations, each of the semiconductor chips 2200 may include a semiconductor memory device described referring to FIG. 1 to FIG. 15. For example, each of the semiconductor chips 2200 may include a peripheral circuit structure PERI and the cell structure CELL stacked on the peripheral circuit structure PERI. For example, the peripheral circuit structure PERI may include a peripheral circuit substrate 300 and the peripheral circuit wiring structure 380 described referring to FIG. 1 to FIG. 15. For example, the cell structure CELL may include a cell substrate 100, a mold structure MS1, a channel structure CH, a bit line BL, a word line contact 160, and a contact spacer 170 described referring to FIG. 1 to FIG. 15.

While this disclosure contains many specific implementation details, these should not be construed as limitations on the scope of what may be claimed, equivalents thereof, as well as claims to be described later. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

What is claimed is:

1. A semiconductor memory device comprising:
a substrate;
a mold structure including a dummy pattern on a partial area of the substrate, a plurality of mold insulating layers, and a plurality of gate electrodes alternately stacked in a first direction on the substrate over the dummy pattern; and
a first word line contact extending into the mold structure and extending in the first direction,
wherein the plurality of gate electrodes include a first gate electrode electrically connected to the first word line contact,
wherein the first gate electrode includes a first conductive plate portion extending in parallel with a surface of the substrate, a second conductive plate portion extending in parallel with the surface of the substrate and disposed at a vertical level different from the first conductive plate portion, and a conductive connection portion connecting the first conductive plate portion to the second conductive plate portion,
wherein a thickness of the conductive connection portion is greater than a thickness of the first conductive plate portion and a thickness of the second conductive plate portion, and
wherein an inner surface of the conductive connection portion contacts an outer surface of the first word line contact.

2. The semiconductor memory device as claimed in claim 1, wherein the first word line contact comprises a vertical contact portion extending into the plurality of mold insulating layers, a first horizontal contact portion extending into the first gate electrode, and a second horizontal contact portion extending into other gate electrodes among the plurality of gate electrodes, and
wherein respective widths of the first horizontal contact portion and the second horizontal contact portion are greater than a width of the vertical contact portion.

3. The semiconductor memory device as claimed in claim 2, wherein the width of the first horizontal contact portion extends by a horizontal distance between a surface of the first conductive plate portion and a surface of a second conductive plate portion facing the first conductive plate portion.

4. The semiconductor memory device as claimed in claim 2, wherein a surface of the first horizontal contact portion has a convex shape protruding in an outward direction of the first horizontal contact portion.

5. The semiconductor memory device as claimed in claim 2, wherein a surface of the first horizontal contact portion has a shape recessed in an inward direction of the first horizontal contact portion.

6. The semiconductor memory device as claimed in claim 1, wherein the first gate electrode and the first word line contact are unitarily formed.

7. The semiconductor memory device as claimed in claim 1,
wherein the plurality of gate electrodes further include a second gate electrode comprising a non-select gate electrode, and
wherein the first word line contact extends into the second gate electrode.

8. The semiconductor memory device as claimed in claim 7, further comprising a contact spacer disposed between the first word line contact and the second gate electrode.

9. The semiconductor memory device as claimed in claim 8, wherein an outer surface of the contact spacer has a convex shape protruding in an outward direction of the contact spacer.

10. The semiconductor memory device as claimed in claim 8, wherein an outer surface of the contact spacer has a shape recessed in an inward direction of the contact spacer.

11. The semiconductor memory device as claimed in claim 1, further comprising a second word line contact spaced apart from the first word line contact in parallel with the surface of the substrate,
wherein a height of the first word line contact is a same as a height of the second word line contact.

12. The semiconductor memory device as claimed in claim 1, further comprising a support structure spaced apart from the first word line contact in a direction parallel with the surface of the substrate,
wherein the support structure includes a vertical support portion extending into the plurality of mold insulating layers, and a horizontal support portion extending into the plurality of gate electrodes, and
wherein a width of the horizontal support portion is greater than a width of the vertical support portion.

13. The semiconductor memory device as claimed in claim 1, wherein each of the plurality of mold insulating layers and each of the plurality of gate electrodes include a step difference surface formed by a thickness of the dummy pattern.

14. The semiconductor memory device as claimed in claim 1, wherein each of the plurality of mold insulating layers comprises:
a first insulating plate portion extending in parallel with the surface of the substrate,
a second insulating plate portion extending in parallel with the surface of the substrate and disposed at a vertical level different from the first insulating plate portion, and
an insulating connecting portion connecting the first insulating plate portion to the second insulating plate portion.

15. A semiconductor memory device comprising:
a peripheral circuit structure; and
a cell structure stacked on the peripheral circuit structure,
wherein the cell structure comprises:
a substrate including a cell array region and an extension region;
a mold structure including a dummy pattern on a partial area of the substrate, a plurality of mold insulating layers, and a plurality of gate electrodes alternately stacked in a first direction on the substrate over the dummy pattern;
a channel structure disposed in the cell array region, the channel structure extending into the mold structure and extending in the first direction; and
a first word line contact disposed in the extension region, the first word line contact extending into the mold structure and extending in the first direction,
wherein the plurality of gate electrodes include a first gate electrode electrically connected to the first word line contact,
wherein the first gate electrode comprises a first conductive plate portion extending in parallel with a surface of the substrate, a second conductive plate portion extending in parallel with the surface of the substrate and disposed at a vertical level different from the first conductive plate portion, and a conductive connection portion connecting the first conductive plate portion to the second conductive plate portion,
wherein a thickness of the conductive connection portion is greater than a thickness of the first conductive plate portion and a thickness of the second conductive plate portion, and
wherein an inner surface of the conductive connection portion contacts an outer surface of the first word line contact.

16. The semiconductor memory device as claimed in claim 15, wherein the dummy pattern is disposed in the cell array region, and the channel structure extends into the dummy pattern.

17. The semiconductor memory device as claimed in claim 15, wherein the dummy pattern is disposed in the extension region.

18. The semiconductor memory device as claimed in claim 15, further comprising a second word line contact spaced apart from the first word line contact in parallel with the surface of the substrate,
wherein a lower surface of the first word line contact is disposed on a same plane as a lower surface of the second word line contact.

19. The semiconductor memory device as claimed in claim 15, further comprising:
a bit line contacting the channel structure, and
a cell wiring structure between the bit line and the peripheral circuit structure, and between the first word line contact and the peripheral circuit structure.

20. An electronic system comprising:
a main substrate;
a semiconductor memory device including a peripheral circuit structure and a cell structure stacked on the peripheral circuit structure on the main substrate; and
a controller electrically connected to the semiconductor memory device on the main substrate,
wherein the cell structure comprises:
a substrate including a cell array region and an extension region;
a mold structure including a dummy pattern disposed on a partial area of the substrate, a plurality of mold insulating layers, and a plurality of gate electrodes alternately stacked in a first direction on the substrate over the dummy pattern;
a channel structure disposed in the cell array region, the channel structure extending into the mold structure and extending in the first direction; and
a first word line contact disposed in the extension region, the first word line contact extending into the mold structure and extending in the first direction,
wherein the plurality of gate electrodes include a first gate electrode electrically connected to the first word line contact,
wherein the first gate electrode includes a first conductive plate portion extending in parallel with a surface of the substrate, a second conductive plate portion extending in parallel with the surface of the substrate and disposed at a vertical level different from the first conductive plate portion, and a conductive connection portion connecting the first conductive plate portion to the second conductive plate portion,
wherein a thickness of the conductive connection portion is greater than a thickness of the first conductive plate portion and a thickness of the second conductive plate portion, and
wherein an inner surface of the conductive connection portion contacts an outer surface of the first word line contact.
